(19) United States
(12) Patent Application Publication
(10) Pub. No.: US 2026/0162852 A1
(43) Pub. Date: Jun. 11, 2026

(54) LOW-IMPEDANCE, HIGH-CURRENT COAXIAL LINE FOR A PLASMA PROCESS SUPPLY SYSTEM, PLASMA PROCESS SYSTEM, AND METHOD FOR OPERATING A PLASMA PROCESS SYSTEM

(71) Applicant: TRUMPF Hüttinger GmbH + Co. KG, Freiburg (DE)

(72) Inventors: Alexander ALT, Freiburg (DE); Birger NORDMANN, Herdecke (DE)

(21) Appl. No.: 19/278,812

(22) Filed: Jul. 24, 2025

Related U.S. Application Data
(63) Continuation of application No. PCT/EP2024/051706, filed on Jan. 25, 2024.

(30) Foreign Application Priority Data
Jan. 25, 2023 (DE) 10 2023 101 789.6

(51) Int. Cl. H01B 11/18; H01J 37/32

(52) U.S. Cl. CPC H01B 11/1843; H01J 37/32174; H01J 37/32577

(57) ABSTRACT

A low-impedance, high-current coaxial line for a plasma process system includes a tubular thermally conductive electric insulator; an electric outer conductor which is arranged on the insulator in the form of an outer layer; and an electric inner conductor which is arranged in the insulator in the form of an inner layer. The inner and outer diameters of the insulator are dimensioned such that the insulator is configured to have a line impedance of ≤20Ω. The low-impedance, high-current coaxial line is configured to connect to an impedance adaptation circuit and a plasma process assembly. The low-impedance, high-current coaxial line is configured to supply the plasma process assembly with high frequency (HF) power by means of an HF power supply.

### CROSS REFERENCE TO RELATED APPLICATIONS

This application is a continuation of International Application No. PCT/EP2024/051706 (WO 2024/156781 A1), filed on Jan. 25, 2024, and claims benefit to German Patent Application No. DE 10 2023 101 789.6, filed on Jan. 25, 2023. The aforementioned applications are hereby incorporated by reference herein.

### FIELD

The present invention relates to a low-impedance, high-current coaxial line for a plasma process supply system and a plasma process system, as well as a method for operating a plasma process system.

### BACKGROUND

Such a plasma process system can, for example, be a system in which a load, for example a plasma process assembly, is supplied with electrical power.

Such a plasma process assembly can, for example, be a plasma process chamber used for industrial plasma processes such as the surface treatment of workpieces, semiconductor manufacturing with plasma or the processing of workpieces with gas lasers.

In such an application, the plasma process assembly is used to generate plasma.

For this purpose, a plasma process assembly can have an electrode which is fed with a high-frequency power signal for generating the plasma, hereinafter referred to as the high frequency (HF) power signal.

Typically, the plasma process assembly can be connected to a high-frequency power supply, hereinafter referred to as an HF power supply.

The HF power signal has a frequency greater than or equal to 4 MHz and in particular less than or equal to 200 MHz. Commonly used frequencies are 13.56 MHz, 27 MHz, and 40 MHz.

U.S. Pat. No. 6,673,724 B2 describes such a plasma process system in which an electrode is additionally exposed to a pulsed RF signal as a so-called “RF-pulsed bias”, wherein the pulse frequency can be in the range of 10 kHz to 1 MHz. Such an arrangement is not easy to implement in practice for various reasons described in more detail below.

The plasma process taking place in the plasma process assembly generally suffers from the problem that the electrical load impedance of the plasma process assembly, which occurs during the process, depends on the conditions in the plasma process assembly and can vary greatly. In particular, the properties of the workpiece, the electrode, and the gas conditions have to be considered.

For this reason, an impedance adaptation circuit is usually required to transform the impedance of the load to a nominal impedance of the HF power supply. Such an impedance adaptation circuit is usually arranged between the HF power supply and the plasma process assembly, usually in the immediate vicinity of the plasma process assembly.

The impedance adaptation circuit and the plasma process assembly are typically connected via interconnects such as copper tabs, bars, or tubes.

Such interconnects exhibit parasitic inductances. These parasitic inductances increase the quality of the load impedance, which leads to a reduction in the possible bandwidth of an impedance adaptation circuit. The quality of an impedance is understood as a factor that expresses the ratio of the stored energy to the thermal energy loss during the following oscillation period in an oscillating system. A high quality of a system means that the system converts the stored energy into thermal energy only to a small extent and the oscillation decreases only to a small extent. Combined with the increased quality and reduced bandwidth, the ability to transmit fast pulses through the impedance adaptation circuit to the plasma process assembly deteriorates.

In addition, the reactive currents in the impedance adaptation circuit increase, thus reducing its efficiency.

### SUMMARY

In an embodiment, the present disclosure provides a low-impedance, high-current coaxial line for a plasma process system. The low-impedance, high-current coaxial line includes a tubular thermally conductive electric insulator; an electric outer conductor which is arranged on the insulator in the form of an outer layer; and an electric inner conductor which is arranged in the insulator in the form of an inner layer. The inner and outer diameters of the insulator are dimensioned such that the insulator is configured to have a line impedance of ≤20Ω. The low-impedance, high-current coaxial line is configured to connect to an impedance adaptation circuit and a plasma process assembly. The low-impedance, high-current coaxial line is configured to supply the plasma process assembly with high frequency (HF) power by means of an HF power supply.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1a shows a schematic cross-sectional view of a first embodiment of a low-impedance, high-current coaxial line according to the invention;

FIG. 1b shows a schematic side view of a first embodiment of a low-impedance, high-current coaxial line according to an embodiment of the invention;

FIG. 2 shows a low-impedance, high-current coaxial line arranged in a plasma process system without an HF power supply according to an embodiment of the invention;

FIG. 3 shows a low-impedance, high-current coaxial line arranged in a plasma process system with an HF power supply according to an embodiment of the invention;

FIG. 4a shows a cross-sectional view of a low-impedance, high-current coaxial line integrated into a cooling device according to an embodiment of the invention; and

FIG. 4b shows a side view of a low-impedance, high-current coaxial line integrated into a cooling device according to an embodiment of the invention.

### DETAILED DESCRIPTION

Embodiments of the present invention provide a high-current coaxial line for a plasma process supply system and a plasma process system, which increases the quality of the load impedance in a plasma process system only slightly or not at all. Embodiments also develop a plasma process supply system and a plasma process system having such a high-current coaxial line and a method for operating a plasma process system.

### DESCRIPTION OF THE INVENTION

Embodiments provide a low-impedance, high-current coaxial line, a plasma process supply system, a plasma process system and/or a method. Advantageous further developments are also provided by the embodiments as described herein.

According to embodiments of the present invention, a low-impedance, high-current coaxial line for a plasma process system is proposed, having:
a tubular thermally conductive electric insulator, in particular embodiments made of ceramic,
an electric outer conductor which is arranged on the insulator in the form of an outer layer,
an electric inner conductor which is arranged in the insulator in the form of an inner layer,
wherein the inner and outer diameters of the insulator are dimensioned such that a line impedance of ≤20Ω can be achieved,
wherein the low-impedance, high-current coaxial line is designed to connect to an impedance adaptation circuit and a plasma process assembly, and
wherein the low-impedance, high-current coaxial line is designed to supply the plasma process assembly with HF power by means of an HF power supply.

In this manner, the quality of the load impedance in the plasma process system can be increased slightly or not at all, and in particular embodiments can even be reduced. And in particular embodiments, this is possible without additional damping measures, such as loss-prone resistors, which would have a negative impact on the efficiency of the plasma process system.

With such a low-impedance, high-current coaxial line, an inductive connection in a plasma process system can be replaced by a coaxial line. In this regard, however, the coaxial line is not a conventional line dimensioned for 50Ω. It is deliberately designed to be much closer to the impedance of the plasma process assembly during operation. This helps to reduce reflections.

Such a plasma process system typically has a plasma process assembly as a load and an impedance adaptation circuit. Furthermore, the plasma process system can also have an HF power supply for providing HF power.

The low-impedance, high-current coaxial line according to embodiments of the invention can interconnect the impedance adaptation circuit and the plasma process assembly in such a plasma process system.

For this purpose, a possible electrode in the plasma process assembly can be contacted with the inner conductor of the low-impedance, high-current coaxial line and connected to a signal in the impedance adaptation circuit. In this context, the outer conductor of the low-impedance, high-current coaxial line can be connected to ground. This ground can be connected to the ground of the impedance adaptation circuit, in particular embodiments to the housing ground thereof. This ground can be connected to the ground of the plasma process assembly, in particular embodiments to the housing ground thereof.

The inner conductor can, in preferred embodiments, be applied to the insulator as a copper and/or silver coating, for example. Such a coating material can have a positive effect on electrical and thermal conductivity.

The tube wall thickness of the tubular thermally conductive electric insulator can be ≤2 mm. This allows the impedance to be adjusted very well and, with the help of the good insulating properties of the insulator, a relatively thin thickness can still insulate the high voltages and prevent flashovers, corona discharges and/or partial discharges.

The outer conductor can, in preferred embodiments, be applied to the insulator as a copper and/or silver coating, for example. Such a coating material can have a positive effect on electrical and thermal conductivity. In addition, the relative permeability of the conductor is close to 1 and there are no negative influences on the skin effect.

The electric inner conductor can be arranged as an inner layer in the insulator in such a way that it is firmly connected to the insulator, in particular embodiments by being applied in a galvanic process, plasma deposition process or sintering process. In this way, a very reliable arrangement can be realized.

The electric outer conductor can be arranged as an outer layer on the insulator in such a way that it is firmly connected to the insulator, in particular embodiments by being applied in a galvanic process, plasma deposition process or sintering process. In this way, a very reliable arrangement can be realized. In addition, the relative permeability of the conductor is close to 1 and there are no negative influences on the skin effect.

By using a thermally conductive electric insulator, the current-carrying capacity of the low-impedance, high-current coaxial line can be greatly increased by means of cooling. In particular embodiments, material for the electric insulator can include ceramic, and in preferred embodiments consists of ceramic. If ceramic is selected as the material, a thin insulation layer can be realized due to its high dielectric strength. With such a thin insulation layer, a particularly low characteristic impedance can also be achieved. The impedance of the cable can therefore be dimensioned by choosing the material and the inner and outer diameter of the insulator.

This provides a low-impedance, high-current coaxial line to which an impedance adaptation circuit and a plasma process assembly can be connected, with little to no increase in the quality of the load impedance, depending on the line impedance in this regard. This allows a higher possible bandwidth of the impedance adaptation circuit, better behavior at high pulse frequencies and better efficiency in the impedance adaptation circuit to be achieved.

The outer conductor of the low-impedance, high-current coaxial line can be designed to be connected to ground. This allows it to be advantageously connected to the plasma process assembly, which is usually also connected to ground.

Furthermore, the outer conductor of the low-impedance, high-current coaxial line can be integrated into a cooling device. Such a cooling device can, in preferred embodiments, be a fluid cooling device made of copper. This allows the low-impedance, high-current coaxial line to be reliably connected thermally and electrically to surrounding systems.

The low-impedance, high-current coaxial line can be designed such that the insulator projects beyond the outer conductor at one end. In other words, the outer conductor of the low-impedance, high-current coaxial line can be designed such that it does not have the same length as the insulator, but is slightly shortened at at least one end, in preferred embodiments at both ends of the insulator. This allows for greater creepage and clearance distances to be achieved, making the low-impedance, high-current coaxial line suitable for higher voltages and thus also for greater power transmission and, at the same time, more reliable ignition.

Furthermore, the inner and outer diameters of the insulator can be selected such that the impedance of the low-impedance, high-current coaxial line is close to the impedance of the plasma process assembly in the state of the ignited plasma. This makes a plasma process system more efficient overall. “Close to the impedance” here means a distance that is less than or equal to 10Ω in terms of absolute value, in particular embodiments less than or equal to 5Ω, particularly preferably less than or equal to 2Ω.

The cavity inside the low-impedance, high-current coaxial line can be filled with a material, in particular embodiments with an air-tight and/or moisture-tight material. In this regard, either the entire cavity or just a part of it can be filled. Since there are no electric or magnetic fields inside of the cavity of the low-impedance, high-current coaxial line, there are only minor restrictions on the choice of material. By filling the cavity of the low-impedance coaxial line, it is possible to achieve a vacuum-tight connection of the low-impedance, high-current coaxial line to an electrode in a plasma process assembly. If the cavity is only partially filled with material, this saves material. By filling the entire cavity, a high stability of the low-impedance, high-current coaxial line is achieved.

Furthermore, the low-impedance, high-current coaxial line can be used in pulsed plasma processing with pulse frequencies of up to 400 kHz.

Advantageously, the low-impedance, high-current coaxial line is designed to supply the plasma process assembly with pulsed HF power, in particular embodiments with a pulse frequency greater than or equal to 200 kHz, wherein the pulsed HF power is provided in particular embodiments by an HF power supply. The pulsed power can advantageously be 400 kHz. The pulsed power can thus be coupled into the plasma process with low reflection and only slight distortion due to the filtering effect of an otherwise significantly mismatched connection. The edge steepness of the pulses in the plasma process can thus be significantly improved.

A further embodiment provides a plasma process supply system having an impedance adaptation circuit and a previously described low-impedance, high-current coaxial line which is connected to the impedance adaptation circuit and is designed to be connected with its other end to a plasma process assembly and thus to establish a connection between the plasma process supply system and the plasma process assembly. In this way, the HF power can be delivered to the plasma process assembly with low reflection.

In a further embodiment, the aforementioned plasma process supply system can have an HF power supply, wherein the impedance adaptation circuit is electrically connected to the HF power supply so that the power supplied by the HF power supply during operation can be supplied to the plasma process assembly via the impedance adaptation circuit and the low-impedance, high-current coaxial line. In this way, the HF power can be delivered to the plasma process assembly with particularly low reflection.

In a further embodiment, one of the aforementioned plasma process supply systems can be designed such that the impedance adaptation circuit is integrated into the HF power supply. In this way, a further improved delivery of the HF power to the plasma process assembly can be achieved.

A further embodiment provides a plasma process system having a previously described plasma process supply system and a plasma process assembly, wherein the low-impedance, high-current coaxial line establishes a connection between the impedance adaptation circuit and the plasma process assembly. In this way, a further improved delivery of the HF power to the plasma process assembly can be achieved.

Arranged in a plasma process system that can include an impedance adaptation circuit, a plasma process assembly, and an HF power supply, a previously described low-impedance, high-current coaxial line can interconnect the impedance adaptation circuit and the plasma process assembly. The impedance adaptation circuit can be arranged within the HF power supply or be integrated into the HF power supply.

Embodiments also provide a method for operating a plasma process assembly with a previously described plasma process supply system, wherein an HF power signal for generating a plasma in the plasma process assembly is guided to this plasma process assembly by means of the low-impedance, high-current coaxial line.

In one aspect of the method for operating a plasma process assembly, the HF power signal for generating the plasma in the plasma process assembly is pulsed between different power levels, in particular embodiments with a pulse frequency greater than or equal to 200 kHz, particularly preferably with a pulse frequency greater than or equal to 400 kHz.

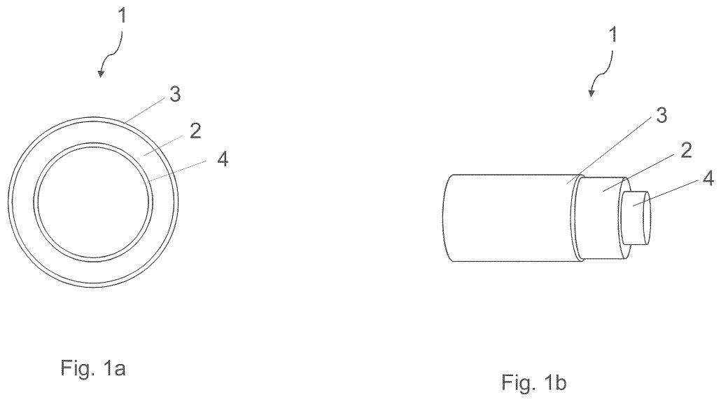

FIGS. 1a and b show a first embodiment of a low-impedance, high-current coaxial line 1 according to an embodiment of the invention. The low-impedance, high-current coaxial line 1 has an insulator 2, an electric inner conductor 4, and an electric outer conductor 3.

The insulator 2 is tubular and made of a thermally conductive and electrically insulating material. The inner conductor 4 is applied as an inner layer on the inside of the insulator 2 and connected thereto. The outer conductor 3 is applied as an outer layer on the outside of the insulator 2 and connected thereto. In FIG. 1a, the low-impedance, high-current coaxial line 1 is shown in a cross-sectional view and in FIG. 1b in a side view. The inner conductor 4 is shown projecting beyond the insulator 2 on one side. This is shown here for better clarity, even if it is often not executed this way. In this regard, the insulator 2 is also shown projecting on one side beyond the outer conductor 3. This can be particularly advantageous when high voltages are to be expected, e.g., at high power levels or during ignition. This then allows the air and creepage distances to be increased. This can increase the dielectric strength.

The low-impedance, high-current coaxial line 1 can be used to connect an impedance adaptation circuit 6 to a plasma process assembly 7.

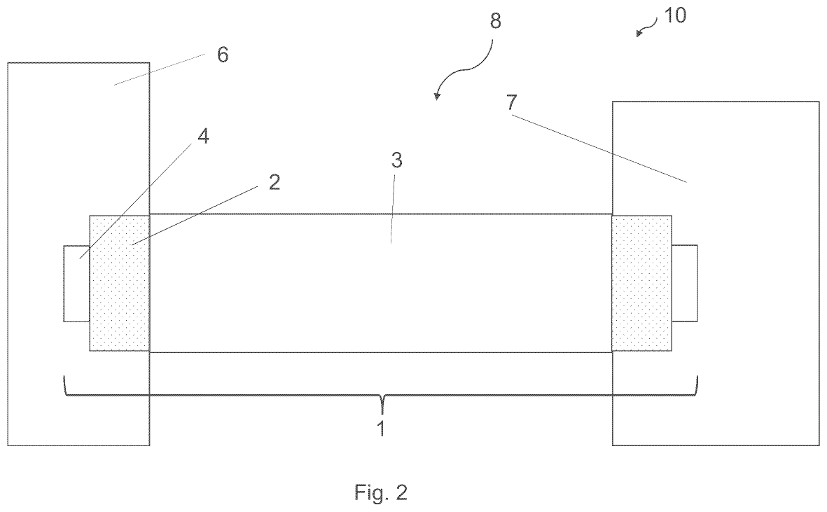

FIG. 2 shows an embodiment of a low-impedance, high-current coaxial line 1 according to an embodiment of the invention arranged in a plasma process system 10, additionally having a plasma process supply system 8 and a plasma process assembly 7.

The low-impedance, high-current coaxial line 1 also has an insulator 2, an inner conductor 4, and an outer conductor 3 here. The plasma process supply system 8 comprises, in addition to the low-impedance, high-current coaxial line 1, an impedance adaptation circuit 6.

The impedance adaptation circuit 6 is connected to the plasma process assembly 7 via the low-impedance, high-current coaxial line 1.

The plasma process assembly 7 is thus connected to the plasma process supply system 8, which together form the plasma process system 10.

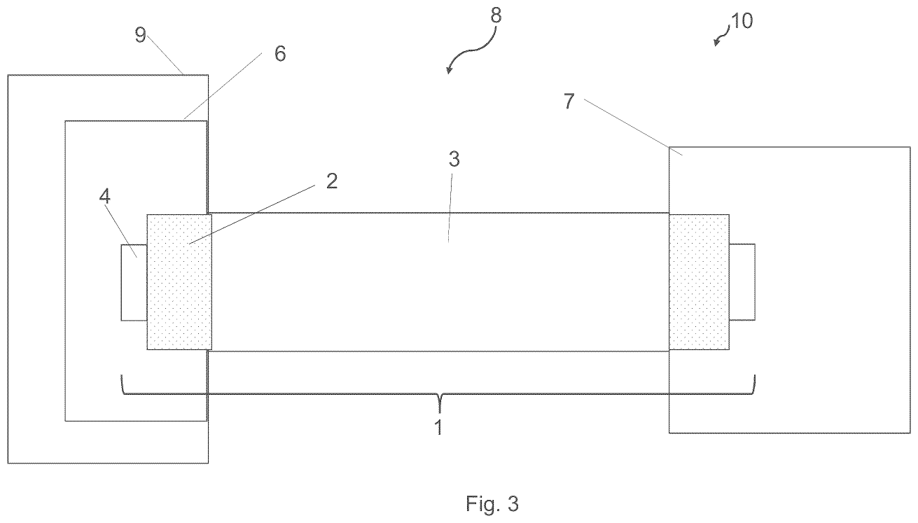

FIG. 3 shows an embodiment of a low-impedance, high-current coaxial line 1 according to an embodiment of the invention arranged in a plasma process system 10 as described in the description of FIG. 2. In this case, the plasma process system 10 contains an additional HF power supply 9 for supplying HF power. The impedance adaptation circuit 6 is arranged here in the HF power supply 9 or integrated into the HF power supply 9. The impedance adaptation circuit 6 can also be arranged separately from the HF power supply 9 in another arrangement. This makes sense in particular embodiments when the HF power supply 9 is far too large or cannot be arranged in the immediate vicinity of the plasma process assembly 7 for other reasons, but the impedance adaptation circuit 6 can.

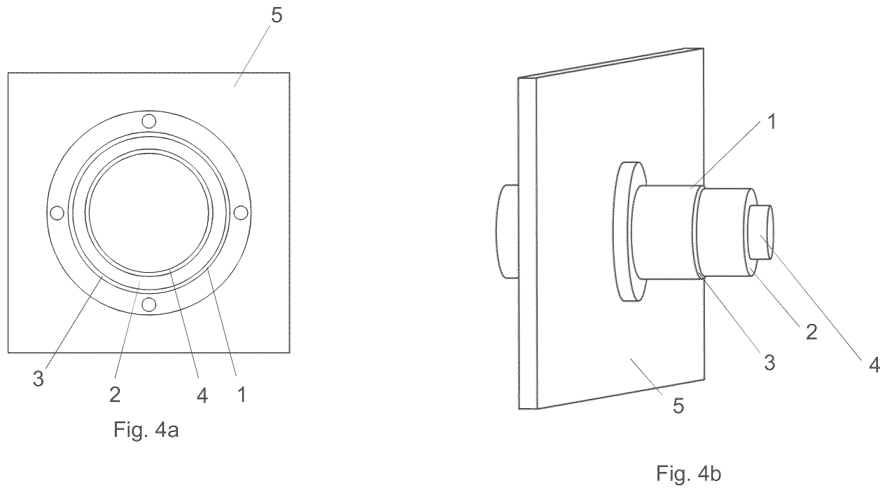

FIGS. 4a and b show an embodiment of a low-impedance, high-current coaxial line 1 according to an embodiment of the invention as described in the description of FIGS. 1a and b.

The low-impedance, high-current coaxial line 1 is integrated into a cooling device 5. The cooling device 5 directly connects to the outer conductor 3 and can preferably be a fluid cooling device having holes for fluid flow. In FIG. 4a, the low-impedance, high-current coaxial line 1 integrated into a cooling device 5 is shown in a cross-sectional view and in FIG. 4b in a side view.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A low-impedance, high-current coaxial line for a plasma process system, comprising:
a tubular thermally conductive electric insulator;
an electric outer conductor which is arranged on the insulator in the form of an outer layer; and
an electric inner conductor which is arranged in the insulator in the form of an inner layer,
wherein the inner and outer diameters of the insulator are dimensioned such that the insulator is configured to have a line impedance of ≤20Ω,
wherein the low-impedance, high-current coaxial line is configured to connect to an impedance adaptation circuit and a plasma process assembly, and
wherein the low-impedance, high-current coaxial line is configured to supply the plasma process assembly with high frequency (HF) power by means of an HF power supply.

2. The low-impedance, high-current coaxial line according to claim 1, wherein the outer conductor is integrated into a fluid cooling device made of copper.

3. The low-impedance, high-current coaxial line according to claim 1, wherein the insulator projects beyond the outer conductor at one end.

4. The low-impedance, high-current coaxial line according to claim 1, wherein the inner and outer diameters of the insulator are configured such that the line impedance is close to the impedance of the plasma process assembly in the state of an ignited plasma.

5. The low-impedance, high-current coaxial line according to claim 1, wherein an inner cavity of the low-impedance, high-current coaxial line is partially filled with a material.

6. The low-impedance, high-current coaxial line according to claim 1, wherein the low-impedance, high-current coaxial line is configured for pulsed plasma processing with pulse frequencies of greater than or equal to 200 kHz.

7. A plasma process supply system comprising an impedance adaptation circuit and the low-impedance, high-current coaxial line according to claim 1, which is connected to the impedance adaptation circuit and is configured to be connected with an end to a plasma process assembly and thus to establish a connection between the plasma process supply system and the plasma process assembly.

8. The plasma process supply system according to claim 7, comprising the HF power supply, wherein the impedance adaptation circuit is electrically connected to the HF power supply so that the power supplied by the HF power supply during operation is configured to be supplied to the plasma process assembly via the impedance adaptation circuit and the low-impedance, high-current coaxial line.

9. The plasma process supply system according to claim 8, wherein the impedance adaptation circuit is integrated into the HF power supply.

10. A plasma process system comprising the plasma process supply system according to claim 7 and the plasma process assembly, wherein the low-impedance, high-current coaxial line establishes a connection between the impedance adaptation circuit and the plasma process assembly.

11. A method for operating the plasma process assembly with the plasma process supply system according to claim 7 or with a plasma process system, wherein an HF power signal for generating a plasma in the plasma process assembly is guided to the plasma process assembly by the low-impedance, high-current coaxial line.

12. The method for operating the plasma process assembly according to claim 11, wherein the HF power signal for generating the plasma in the plasma process assembly is pulsed between different power levels with a pulse frequency greater than or equal to 200 kHz.

13. The low-impedance, high-current coaxial line according to claim 1, wherein the tubular thermally conductive insulator is made of ceramic.

14. The low-impedance, high-current coaxial line according to claim 1, wherein the low-impedance, high-current coaxial line is configured for pulsed plasma processing with pulse frequencies of greater than or equal to 400 kHz.

15. The method for operating the plasma process assembly according to claim 11, wherein the HF power signal for generating the plasma in the plasma process assembly is pulsed between different power levels with a pulse frequency greater than or equal to 400 kHz.
